(19) United States
(12) Patent Application Publication
(10) Pub. No.: US 2010/0019392 A1
(43) Pub. Date: Jan. 28, 2010

(54) STACKED DIE PACKAGE HAVING REDUCED HEIGHT AND METHOD OF MAKING SAME

(76) Inventors: Tan Gin Ghee, Penang (MY); Leow Hong Keat, Penang (MY)

Correspondence Address: SPANSION LLC C/O MURABITO , HAO & BARNES LLP, TWO NORTH MARKET STREET, THRID FLOOR, SAN JOSE, CA, 95113, US

(21) Appl. No.: 12/180,185

(22) Filed: Jul. 25, 2008

(51) Int. Cl. H01L 23/49; H01L 21/56

(52) U.S. Cl. 257/777; 438/108; 257/E23.024; 257/E21.502

(57) ABSTRACT

A stacked die package is disclosed. The stacked die package includes a wire-bond die that is electrically coupled to other components via one or more wire bonds and a flip-chip die that is coupled to the top surface of the wire-bond die via one or more solder joints. The wire-bond die is formed underneath the flip-chip die. A space defined by the height of the loops of the one or more wire-bonds overlap a space defined by the thickness of one or more solder joints.

### FIELD OF THE INVENTION

The present invention relates to stacked die packages.

### BACKGROUND

Consumer electronic products such as televisions, digital cameras, cellular telephones, media content players, etc., help to satisfy consumer demand for basic communications and entertainment services. Electronic components such as data processing and storage components play an important role in the operation of these devices. Moreover, smaller sized consumer electronic products require such components to be small in size.

The manufacture of small sized consumer electronic products such as cell phones and pocket PCs requires the maximum possible functional integration in packaging and seeks components that provide the smallest footprint (e.g., base dimensions), lowest profile (e.g., thickness) and lowest cost. Stacked-die chip scale packages (CSPs) integrate an ASIC and memories such as flash, SRAM and DDR into one package by stacking the respective dies.

FIG. 1A shows a conventional stacked-die package arrangement 100 that includes two stacked wire bond dies 101 and 103. Referring to FIG. 1A stacked wire bond dies 101 and 103 are attached using a die attach film/paste 105. Moreover, stacked wire bond dies 101 and 103 are encapsulated in molding 107. In addition, wire bond dies 101 and 103 are connected to other electronics via wire bonds 109. As shown in FIG. 1A, wire bonds 109 include a loop portion (see encircled portion of wire bond 109 labeled “A”) that vertically extends above the surface of the top die 101. The vertical distance to which the loop portion extends above the surface of the top die 101 is referred to as “loop height”. Bottom die 103 is connected to solderballs 111 through vias 113. Referring again to FIG. 1A, it should be appreciated that the space occupied by the loops of wire bonds 109 must be accommodated in the fabrication of stacked die packages which can add significantly to package thickness.

Another type of conventional stacked-die package arrangement that includes both a wire bond die and a flip chip die is shown in FIG. 1B. Referring to FIG. 1B, stacked-die package 150 includes wire bond die 151 disposed atop flip chip die 153. Moreover, wire bond die 151 and flip chip die 153 are encapsulated in package molding 157. Wire bonds 159 provide electrical connections between wire bond die 151 and other electronic components, and flip chip die 153 is connected to solderballs via wiring layer 155. Wiring layer 155 is connected to solderballs 161 through vias 163. It should be appreciated that wire bonds 159 are characterized by a loop (see encircled portion of wire bond 159 labeled “B”) that vertically extends above the surface of the wire bond die 151. Referring again to FIG. 1B, as discussed above, the vertical distance that the loop extends above the surface of wire bond die 151 (the loop height) must be accommodated in the fabrication of the stacked-die package 150.

As is clear from the above discussion, managing the loop height of wire bonds can be a critical part of achieving low profile packaging in stacked-die packages. It should be appreciated that on any top die, the loop top must clear the mold cap and leave enough clearance for laser marking depth. Moreover, on any bottom die with a spacer on top of it, the loop must clear the die above and thus controls to a large extent the spacer thickness.

Conventional approaches to fabricating stacked die packages can be inadequate as the loop height of wire bonds limit achievable minimum package thicknesses. Accordingly, using such approaches, achievable reductions in total package height of stacked-die packages, which is an important aspect of the fabrication of handheld consumer products (e.g., cellular telephones etc.), is very much limited.

### SUMMARY OF THE INVENTION

A stacked die package is disclosed. The stacked die package includes a wire-bond die that is electrically coupled to other components via one or more wire bonds and a flip-chip die that is coupled to the top surface of the wire-bond die via one or more solder joints. The wire-bond die is formed underneath the flip-chip die. A space defined by the height of the loops of the one or more wire-bonds overlap a space defined by the thickness of one or more solder joints.

### BRIEF DESCRIPTION OF THE DRAWINGS

The invention, together with further advantages thereof, may best be understood by reference to the following description taken in conjunction with the accompanying drawings in which:

FIG. 1A shows a conventional stacked die package that includes stacked wire bond dies.

FIG. 1B shows another conventional stacked die package that includes both a wire bond die and a flip chip die.

FIG. 2 shows a diagram that illustrates how a reduction in package height allows a thin stacked die package to be used in smaller sized electronic devices according to one embodiment of the present invention.

FIG. 3A shows a thin stacked die package according to one embodiment of the present invention.

FIG. 3B illustrates how package height can be reduced by constructing stacked die packages that have wire bond loops and solder joints whose vertical dimensions define spaces that overlap coextensively according to one embodiment.

FIG. 3C illustrates how package height can be reduced by constructing stacked die packages that have wire bond loops and solder joints whose vertical dimensions define spaces that overlap where the space defined by the vertical dimension of the wire bond loops is less than that defined by the vertical dimension of the solder joints according to one embodiment.

FIG. 3D illustrates how package height can be reduced by constructing stacked die packages that have wire bond loops and solder joints whose vertical dimensions define spaces that overlap where the space defined by the vertical dimension of the wire bond loops is greater than that defined by the vertical dimension of the solder joints according to one embodiment.

FIG. 3E illustrates how package height can be reduced by constructing stacked die packages that have wire bond loops and solder joints whose vertical dimensions define spaces that overlap where the wire bond loops lie underneath a flip-chip according to one embodiment.

FIG. 3F illustrates how package height can be reduced by constructing stacked die packages that have wire bond loops and solder joints whose vertical dimensions define spaces that overlap where the wire bond loops lie underneath a flip-chip and the flip-chip is encapsulated by package molding according to one embodiment.

FIG. 4 shows a thin stacked die package with multiple wire bond dies according to one embodiment of the present invention.

FIG. 5 shows an exemplary top view of a wire bond die having a redistribution layer (RDL) on its top surface according to one embodiment.

FIG. 6 shows a flowchart of the steps performed in a method for fabricating a thin stacked die package having reduced height according to one embodiment.

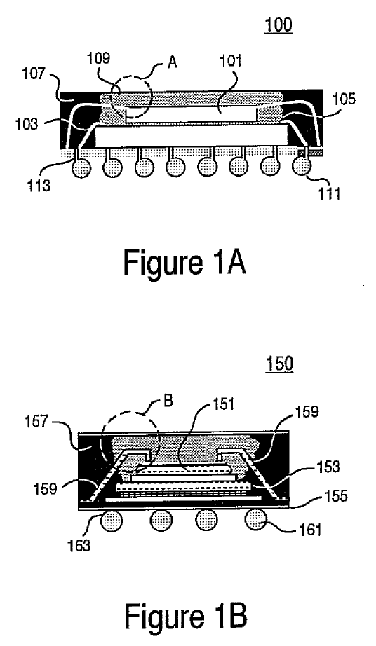

It should be noted that like reference numbers refer to like elements in the figures.

### DETAILED DESCRIPTION OF THE INVENTION

The present invention will now be described in detail with reference to a various embodiments thereof as illustrated in the accompanying drawings. In the following description, specific details are set forth in order to provide a thorough understanding of the present invention. It will be apparent, however, to one skilled in the art, that the present invention may be practiced without using some of the implementation details set forth herein. It should also be understood that well known operations have not been described in detail in order to not unnecessarily obscure the present invention.

### Reduction of Thin Stacked Die Package Height According to One Embodiment of the Present Invention

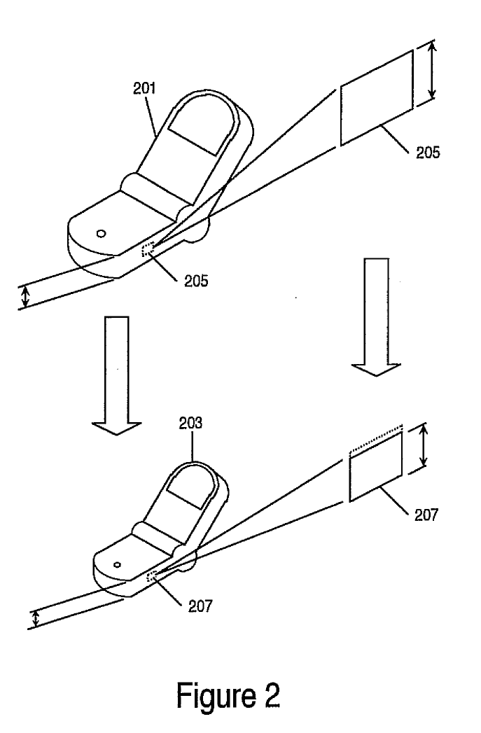

FIG. 2 shows a diagram that illustrates how a reduction in package height allows a thin stacked die package to be used in smaller sized electronic devices according to one embodiment of the present invention. In one embodiment, the processes described herein enable such a reduction in package height of stacked die packages. It should be appreciated that such reductions in package height can help to meet the requirement of smaller sized electronic devices for smaller internal components. FIG. 2 shows cellular telephone 201, cellular telephone 203, stacked die package 205 and thin stacked die package 207.

Referring to FIG. 2, cellular telephone 201 includes stacked die package 205. It should be appreciated that stacked die package 205 is formed using conventional processes that stack the dies in a manner that requires the wire bond loops and the solder joints associated with stacked dies that are a part of stacked die package to occupy separate spaces in the stacked die package. Such an arrangement adds to the thickness of stacked die package 205. Importantly, the package height of stacked die package 205, which is due in some measure to the aforementioned conventional die stacking scheme, can limit the electronic devices for which stacked die package 205 may be suitable for use.

It should be appreciated that processes described herein enable the manufacture of integrated circuits that have thinner packages. As shown in FIG. 2, the thin stacked die package processes described herein enable the manufacture of stacked die packages, with similar content to conventionally manufactured stacked die packages, that have thinner packaging and that are suitable for smaller electronic devices such as cellular telephone 203 (smaller as compared to cellular telephone 201).

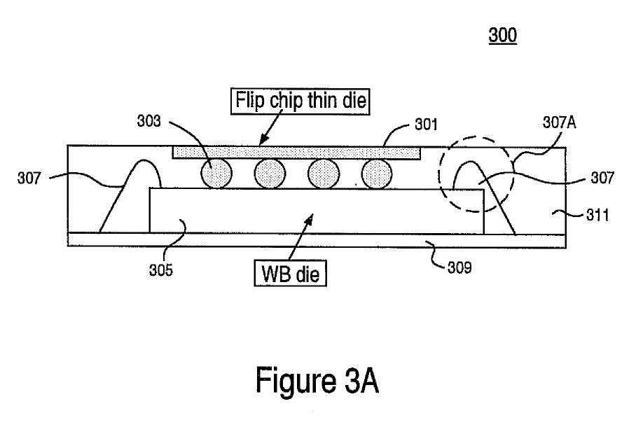

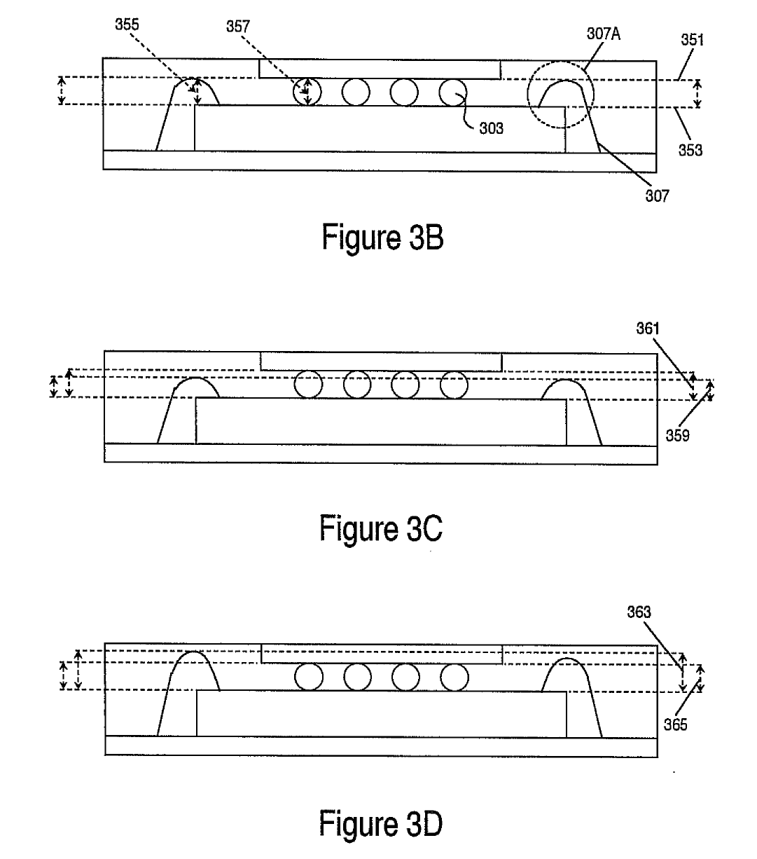

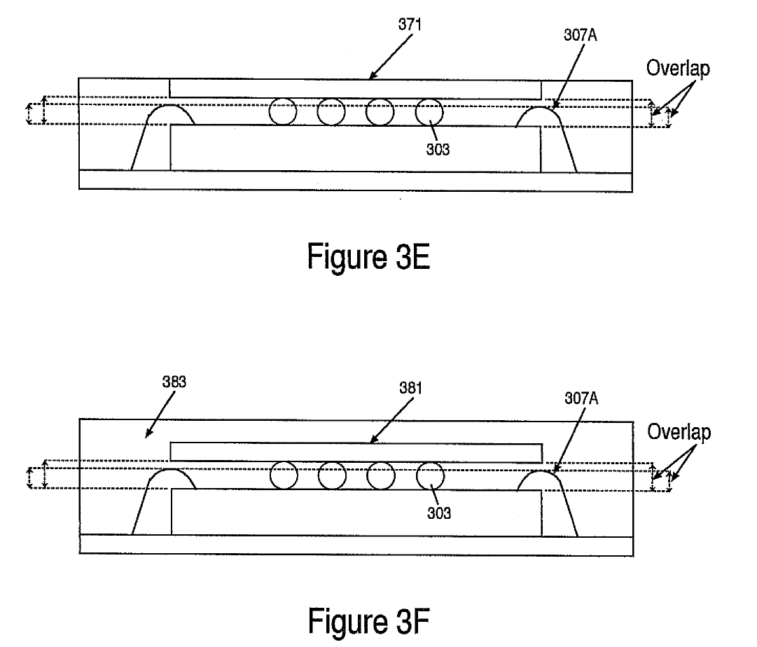

Referring again to FIG. 2, cellular telephone 203 includes thin stacked die package 207. It should be appreciated that thin stacked die package 207 is formed such that space occupied by components of the stacked dies which it includes overlap, which saves package space and enables a reduction in the thickness of thin die stacked package 207 as compared to conventional stacked die package 205 (see discussions made with reference to FIGS. 3A through 3D). The thinner package height of thin stacked die package 207 is a factor as it regards its suitability for use with smaller sized electronic devices.

### Stacked Die Package Having Reduced Height and Method of Making Same According to One Embodiment of the Present Invention

FIG. 3A shows a thin stacked die package 300 according to one embodiment of the present invention. Exemplary embodiments feature thinner package heights as compared to conventional stacked die packages. The smaller sized packages are facilitated by the die stacking scheme that is employed which features a flip-chip die disposed atop a wire bond die. This arrangement provides package height savings due to the overlap of vertical package space occupied by flip-chip solder joints and wire bond loops. In addition, this arrangement facilitates the backgrinding/polishing of package and flip-chip molding that taken together results in a significantly thinner stacked die package as compared to conventional stacked die packages that contain similar components. FIG. 3A shows a stacked die package that includes flip-chip thin die 301, solder joints 303, wire-bond die 305, wire bonds 307, wire bond loops 307A, substrate 309 and encapsulation 311.

Referring to FIG. 3A, flip-chip thin die 301 is disposed atop bottom wire bond die 305. In the FIG. 3A embodiment, flip-chip thin die 301 is coupled to bottom wire bond die 305 via solder joints 303. Moreover, flip-chip thin die 301 is disposed to have its back surface exposed at the top surface of thin stacked die package 300. In one embodiment, the back surface of flip-chip thin die 301 is disposed to be coincident with the top surface of thin stacked die package 300 which is formed by encapsulation 311.

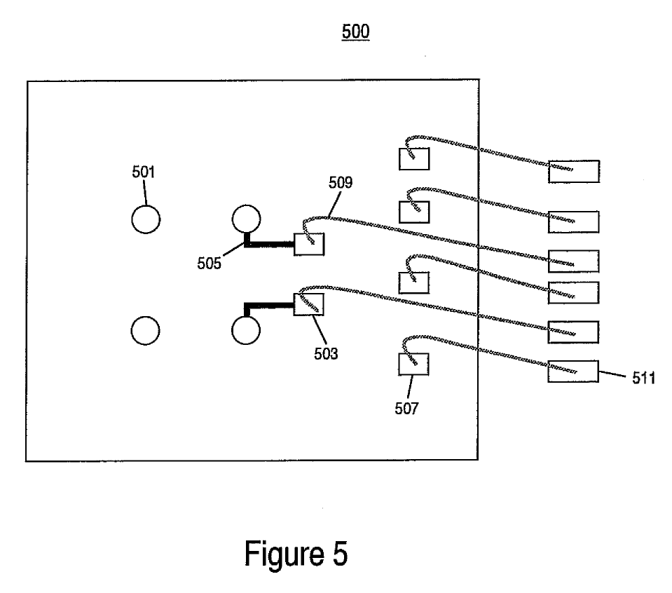

Referring again to FIG. 3A, bottom wire bond die 305 is attached to substrate 309 and includes a redistribution layer (RDL) on its top surface that facilitates a connection with flip-chip thin die 301 (discussed herein in detail below with reference to FIG. 5). Moreover, bottom wire bond die 305 includes wire bond 307 that provides an electrical connection between bottom wire bond die 305 and other electronics. Wire bond 305 includes wire bond loop 307A that is characterized by a “loop height” that is measured from the top surface of bottom wire bond die 305 to the topmost point of wire bond loop 307A.

As discussed above, by disposing flip-chip thin die 301 atop wire bond die 305 as shown in FIG. 3A, the vertical spaces (spaces between parallel horizontal lines) defined by the thickness of flip-chip solder joint 303 and the loop height of wire bond loop 307A overlap. In one embodiment, the overlapping of the vertical spaces defined by flip-chip solder joint 303 and wire bond loop 307A saves package space as vertical package space is shared by flip-chip solder joint 303 and wire bond loop 307A which enables the thickness of the stacked package to be reduced. Such size reduction is advantageous for stacked die packages that are used, for example, in hand held devices that are smaller in size as compared to most other electronic devices.

In one embodiment by stacking flip-chip thin die 301 (top die) atop wire-bond die 305 (bottom die), the molded part of package 300 can be polished or back-grinded to expose the back of flip-chip thin die 301. In one embodiment, the process of polishing or back-grinding the molded part of package 300 operates to further reduce the total package height of the stacked die package 300. In addition, the exposed back of flip-chip thin die 301 can enhance heat dissipation so that better thermal performance can be achieved.

In one embodiment, as mentioned above, a redistribution layer (RDL) (see FIG. 5 discussion below) can be formed on wire-bond bottom die 305 to accommodate the attachment of flip-chip thin die 305. Moreover, a re-layout pad can be created on the sides of wire-bond die 305 as an in-line bond pad or as a staggered wire bond pad on wire-bond die 305 to connect a flip-chip bond to the substrate through a wire bond (see FIG. 5 and accompanying discussion below).

In one embodiment, standard processes can be used to provide an LGA, QFP, BGA package. As discussed above, the configuration can be applied for multiple stacked die (more than two dies) especially for the last two upper top die.

In some embodiments, solderless flip-chip attachment methods such as thermosonic/thermocompression flip-chip attachment methods can be used.

FIGS. 3B through 3F illustrate how package height can be reduced using a die stacking scheme that features wire bond loops and solder joints whose vertical dimensions define spaces that overlap according to one embodiment. Referring to FIG. 3B, vertical package space 350 occupied by wire bond loops 307A and solder joints 303 is identified by dashed lines 351 and 353. As shown in FIG. 3B, the vertical spaces defined by the vertical dimensions 355 and 357, of wire bond loops 307A and solder joints 303 respectively, completely overlap as the vertical spaces defined by these components are substantially coextensive. Accordingly, vertical package space in excess of that needed to accommodate solder joints 303 is unnecessary to accommodate wire bond loops 307A. In the FIG. 3C illustration, the vertical spaces defined by the vertical dimensions 359 and 361 of wire bond loops 307A and solder joints 303 overlap. Accordingly, as in the FIG. 3B case, vertical package space in addition to that needed to accommodate solder joints 303 is unnecessary to accommodate wire bond loops 307A as the vertical package space needed to accommodate wire bond loops 307A is less than that, and is subsumed by that, needed to accommodate solder joints 303. In the FIG. 3D illustration, the vertical spaces defined by the vertical dimensions 363 and 365 of wire bond loops 307A and solder joints 303 partially overlap, with the vertical dimension (loop height) of wire bond loops 307A extending above the vertical dimension of the solder joints 303. However, as shown in FIG. 3D a large amount of the space defined by the vertical dimension (loop height) of wire bond loops 307A overlaps with that defined by the vertical dimension (thickness) of solder joints 303. Accordingly, the amount of vertical package space in the resultant stacked die package needed to accommodate wire bond loops 307A is reduced by the aforementioned overlap of the vertical spaces defined by the vertical dimensions of wire bond loops 307A and solder joints 303.

FIGS. 3E and 3F illustrate respective versions of the FIG. 3C case described above, but feature a flip-chip that is positioned to extend horizontally above wire bond loops 307A such that the wire bond loops or portions thereof are located underneath the flip-chip. The FIG. 3E embodiment features an exposed flip-chip backside 371. However, the FIG. 3F embodiment features a flip-chip backside 381 that is encapsulated by package molding 383 and thus is not exposed. Nevertheless, in both the FIG. 3E and FIG. 3F embodiments, the vertical spaces defined by the vertical dimensions of wire bond loops 307A and solder joints 303 overlap, with the vertical space defined by solder joints 303 subsuming that which is defined by wire bond loops 307A (see arrows indicating overlap). Accordingly, vertical package space in addition to that which is needed to accommodate solder joints 303 is unnecessary to accommodate wire bond loops 307A. In each of the cases illustrated in FIGS. 3B through 3F, the resultant stacked die package height is reduced as compared to conventional stacked die packages as the vertical package space that is used to accommodate wire bond loops and solder joints is at least partially shared by these components, and thus the need to have entirely separate vertical package spaces accommodate them is eliminated.

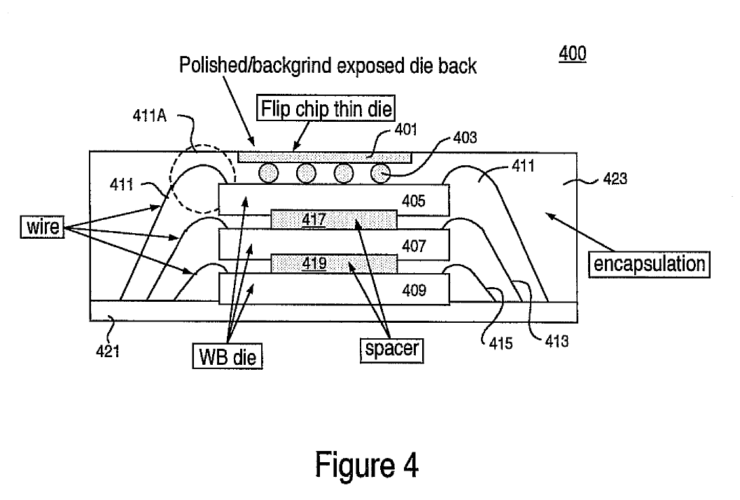

FIG. 4 shows a stacked die package 400 that includes multiple wire bond dies according to one embodiment of the present invention. In the FIG. 4 embodiment, stacked die package 400 includes flip chip thin die 401, solder joints 403, wire bond die 405, wire bond die 407, wire bond die 409, wire bond 411, wire bond loop 411A, wire bond 413, wire bond 415, spacer 417, spacer 419, substrate 421 and encapsulation 423.

Referring to FIG. 4, flip-chip thin die 401 is disposed atop bottom wire bond die 405. In the FIG. 4 embodiment, flip-chip thin die 401 is coupled to bottom wire bond die 405 via solder joints 403. In one embodiment, such as shown in FIG. 4, the back surface of flip-chip thin die 401 is exposed at the top surface of stacked die package 400. Moreover, the back surface of flip-chip thin die 401 is disposed to be coincident with the top surface of stacked die package 400 which is formed by encapsulation 423.

In the FIG. 4 embodiment, bottom wire bond die 405 is attached to wire bond die 407 via spacer 417 and includes top surface wiring to facilitate a connection with flip-chip thin die 401 that is disposed atop wire bond die 405 (see discussion made with reference to FIG. 5 below). Moreover, bottom wire bond die 405 is coupled to wire bond 411 that provides an electrical connection between bottom wire bond die 405 and other electronics.

In the FIG. 4 embodiment, wire bond die 407 is attached to wire bond die 405 and wire bond die 409 via spacers 417 and 419 respectively. Wire bond die 405 is disposed atop wire bond die 407 and wire bond die 407 is disposed atop wire bond die 409. Moreover, wire bond die 407 is coupled to wire bond 413 that provides an electrical connection between wire bond die 407 and other electronics.

In the FIG. 4 embodiment, wire bond die 409 is disposed atop substrate 421 and is attached to the bottom of wire bond die 407 via spacer 419. Moreover, wire bond die 409 is coupled to wire bonds 415 that provide electrical connection between wire bond die 409 and other electronics. It should be appreciated that as with the FIG. 3 embodiment, the height of stacked die package 400 is thinner as compared to conventional stacked die packages as the vertical space that is used to accommodate wire bond loops 411A and solder joints 403 is shared, which eliminates the need to use entirely separate vertical spaces (which adds to package thickness) to accommodate these structures.

FIG. 5 shows an exemplary top view of a wire bond chip 500 having a redistribution layer (RDL) on its top surface according to one embodiment. In exemplary embodiments, the RDL accommodates the flip chip arrangement discussed with reference to FIGS. 3A-3D and FIG. 4. FIG. 5 shows RDL bump pad for flip chip attach 501, RDL wire bond pad for wire bonding 503, RDL metal trace 505, original wire bond pad 507, wire bond interconnection 509 and substrate/lead frame pad for wire bonding 511.

Referring to FIG. 5, RDL bump pad for flip chip attach 501, RDL wire bond pad for wire bonding 503 and RDL metal trace 505 are added to the top of a wire bond die (e.g., 305 in FIG. 3A) to accommodate the coupling of a flip chip as discussed herein. RDL pad for flip chip attach 501 accommodates the solder joints that couple the flip chip (e.g., 301 in FIG. 3A) to the wire bond die. RDL wire bond pad 503 facilitates the electrical coupling of the flip chip to external sources. RDL metal trace 505 electrically couples the flip chip solder joints to the RDL wire bond pads 503. Wire bond interconnections 509 provide electrical connection to substrate/lead frame pad for wire bonding 511, which in turn provides electrical connection to external components. In one embodiment, these structures accommodate the electrical connection of a flip chip (e.g., 301 in FIG. 3A) to a bottom wire bond die (e.g., 305 in FIG. 3A) and to external circuitry in a manner that enables the overlap, in vertical space of the stacked die package, of the vertical spaces defined by vertical dimensions of associated wire bond loops and solder joints (and thus their sharing of vertical space) as discussed above to facilitate a reduction in package height.

### Exemplary Operations for Fabricating a Stacked Die Package Having Reduced Height According to One Embodiment of the Present Invention

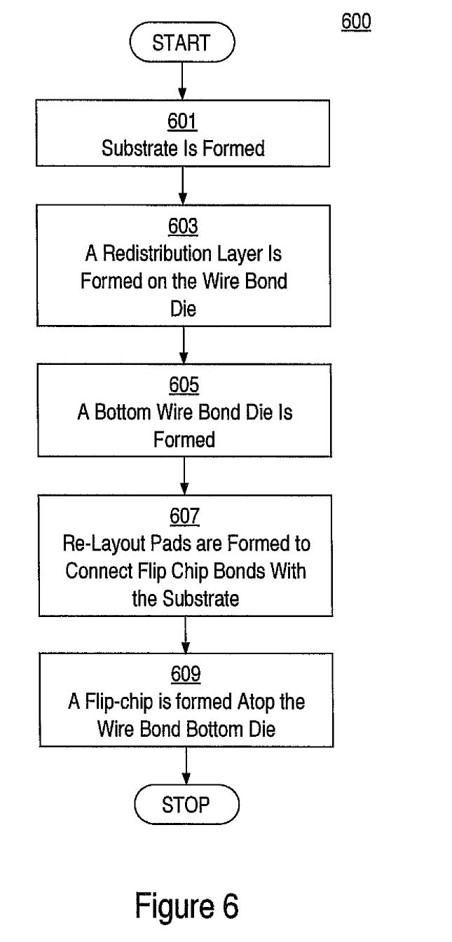

FIG. 6 shows a flowchart 600 of the steps performed in a method for fabricating a thin stacked die package having reduced height according to one embodiment. Although specific steps are disclosed in the flowcharts, such steps are exemplary. That is the present invention is well suited to performing various other steps or variations of the steps recited in the flowcharts.

Referring to FIG. 6, at 601 a substrate is formed.

At 603, a redistribution layer (RDL) is formed on a wire bond die. In one embodiment, the RDL is formed on the bottom wire bond die to accommodate a flip-chip attachment (e.g., by creating bump pads).

At 605, the bottom wire bond die is formed on the substrate. It should be appreciated that the bottom wire bond die may be coupled to one or more wire bonds that provide an electrical connection between the bottom wire bond die and other electronics.

At 607, re-layout pads are formed to connect flip-chip bonds to the substrate through wire-bonds. In one embodiment, the re-layout pads are formed either on sides of the wire bond die or as staggered wire bond pads on the existing wire bond die.

At 609, a flip-chip is formed atop the wire-bond bottom die. In one embodiment, the flip-chip is formed atop the wire-bond die in a manner where the vertical space defined by the wire bond loop of the wire bond die and the vertical space defined by the solder joints overlap.

With reference to exemplary embodiments thereof, a stacked die package is disclosed. The stacked die package includes a wire-bond die that is electrically coupled to other components via one or more wire bonds and a flip-chip die that is coupled to the top surface of the wire-bond die via one or more solder joints. The wire-bond die is formed underneath the flip-chip die. A space defined by the height of the loops of the one or more wire-bonds overlap a space defined by the thickness of one or more solder joints.

Although many of the components and processes are described above in the singular for convenience, it will be appreciated by one of skill in the art that multiple components and repeated processes can also be used to practice the techniques of the present invention. Further, while the invention has been particularly shown and described with reference to specific embodiments thereof, it will be understood by those skilled in the art that changes in the form and details of the disclosed embodiments may be made without departing from the spirit or scope of the invention. For example, embodiments of the present invention may be employed with a variety of components and should not be restricted to the ones mentioned above. It is therefore intended that the invention be interpreted to include all variations and equivalents that fall within the true spirit and scope of the present invention.

We claim:

1. A stacked die package, comprising:
a wire-bond die, wherein said wire-bond die is coupled to one or more wire bonds; and
a flip-chip die coupled to the top surface of said wire-bond die via one or more solder joints, wherein said wire-bond die is formed underneath said flip-chip die and wherein a space defined by the height of loops of said one or more wire-bonds, overlaps a space defined by the thickness of said one or more solder joints.

2. The stacked die package of claim 1 further comprising a molding that encapsulates said wire-bond die and said flip-chip die.

3. The stacked die package of claim 2 wherein said flip-chip die is thinned by polishing said molding that encapsulates said flip-chip die.

4. The stacked die package of claim 3 wherein said back surface of said flip-chip die is exposed and is coincident with the top surface of said stacked die package.

5. The stacked die package of claim 3 further comprising an external heat dissipating element that is attached to said back surface of said flip-chip die.

6. The stacked die package of claim 1 wherein said wire-bond die comprises a redistribution layer on its top surface.

7. The stacked die package of claim 1 further comprising staggered wire-bond pads on said wire bond die for connecting a flip chip bond to a substrate through a wire bond.

8. A stacked die package, comprising:
a plurality of wire-bond dies coupled to one or more wire bonds; and
a flip-chip die coupled to the top surface of one of said plurality of wire-bond dies by one or more solder joints, wherein said plurality of wire-bond dies are formed underneath said flip-chip die and wherein a space defined by a vertical dimension of a wire-bond loop and a space defined by a vertical dimension of said solder joints overlap.

9. The stacked die package of claim 8 further comprising a molding that encapsulates said wire-bond die and said flip-chip die.

10. The stacked die package of claim 9 wherein said flip-chip die is thinned by polishing said molding that encapsulates said flip-chip die.

11. The stacked die package of claim 10 wherein said back surface of said flip-chip die is exposed and is coincident with the top surface of said stacked die package.

12. The stacked die package of claim 10 further comprising an external heat dissipating element that is attached to said back surface of said flip-chip die.

13. The stacked die package of claim 8 wherein said one of said wire bond dies comprises a redistribution layer (RDL).

14. The stacked die package of claim 8 further comprising staggered wire-bond pads on said one of said wire bond dies for connecting a flip chip bond to a substrate through a wire bond.

15. A method for fabricating a stacked die package, comprising:
forming a substrate;
forming a wire-bond bottom die on said substrate;
forming a redistribution layer (RDL) on said wire-bond bottom die;
forming a re-layout to connect a flip-chip bond to said substrate through a wire-bond; and
forming a flip-chip die on said wire-bond bottom die, wherein said wire-bond bottom die is formed underneath said flip-chip die and wherein spaces defined by a wire-bond loop height of a wire bond associated with said wire-bond bottom die and a thickness of a solder joint associated with said flip-chip overlap.

16. The method of claim 15 further comprising forming a molding that encapsulates said wire-bond bottom die and said flip-chip die.

17. The method of claim 16 wherein said flip-chip die is thinned by polishing said molding that encapsulates said flip-chip die.

18. The method of claim 17 wherein said back surface of said flip-chip die is exposed and is coincident with the top surface of said stacked die package.

19. The method of claim 17 further comprising:
attaching an external heat dissipating element to said back surface of said flip-chip die.

20. The method of claim 15 wherein said forming a redistribution layer further comprises forming bump-pads on said wire-bond die.
